(19) United States
(12) Patent Application Publication
(10) Pub. No.: US 2026/0276728 A1
(43) Pub. Date: Sep. 17, 2026

(54) LITHIUM BATTERY HEALTH

(71) Applicant: Worcester Polytechnic Institute, Worcester, MA (US)

(72) Inventors: Zhu Mao, Worcester, MA (US); Yujie Xi, Westborough, MA (US); Ethan Zhou, Westborough, MA (US)

(21) Appl. No.: 19/565,223

(22) Filed: Mar. 12, 2026

Related U.S. Application Data
(60) Provisional application No. 63/771,522, filed on Mar. 13, 2025.

(51) Int. Cl. G01R 31/392; G01H 1/14; G01H 11/08; G01R 31/367; G01R 31/396; H01M 10/42

(52) U.S. Cl. CPC G01R 31/392; G01H 1/14; G01H 11/08; G01R 31/367; G01R 31/396; H01M 10/425

(57) ABSTRACT

A vibration-based non-destructive assessment technique for lithium-ion battery (LIB) health addresses a need for an early warning system to detect battery damage or malfunction that electrical signals alone may miss, particularly in the context of thermal runaway risks. A method of evaluating battery health includes applying a stimulus signal to a sensor adhered to an exterior surface of a battery cell, and receiving a vibration signal responsive to the stimulus signal indicative of a vibration of the battery cell. A computation application or instruction set computes battery health based on the vibration signal.

### RELATED APPLICATIONS

This patent application claims the benefit under 35 U.S.C. § 119 (e) of U.S. Provisional Patent App. No. 63/771,522 filed Mar. 13, 2025, incorporated herein by reference in entirety.

### BACKGROUND

Batteries store and release electrical energy through electrochemical reactions and a connection to a charge source or load. Battery usage, and in particular lithium-ion (Li-ion) batteries, has increased in recent decades due to the high energy density and discharge rates of the Li-ion battery chemistry. Electric vehicles (EVs), personal devices such as cell phones and smartphones, and utility devices such as power tools and home appliances tend to favor EV batteries for an ability to reliably store and release electrical energy (electricity).

Batteries are typically charged and discharged over many cycles in a usage context. Charging occurs from connection to a fixed power source, usually from an AC outlet sourced from the electrical grid. Once charged, the battery is connected to a load such as an EV or utility device and provides power up to the limit of stored electrical energy in the battery. For Li-ion batteries in particular, the charging process is sensitive to voltage and charge levels, and if not maintained within certain ranges, can compromise battery health and ability to hold a charge, and can even create a potentially dangerous situation from runaway discharge.

### SUMMARY

A vibration-based non-destructive assessment technique for lithium-ion battery (LIB) health addresses a need for an early warning system to detect battery damage or malfunction that electrical signals alone may miss, particularly in the context of thermal runaway risks. A method of evaluating battery health includes applying a stimulus signal to a sensor adhered to an exterior surface of a battery cell, and receiving a vibration signal responsive to the stimulus signal indicative of a vibration of the battery cell. A computation application or instruction set evaluates battery health based on the vibration signal.

Configurations herein are based, in part, on the observation that batteries, and in particular Li-ion batteries, are commonly used as mobile power supplies in vehicles, personal devices and utility tools. Li-ion batteries have gained favor due to beneficial storage capacity and high discharge (power supply) rates, however rechargeable batteries in general operate on an analogous charge and discharge ability from electrochemical reactions within the battery, and may benefit from configurations herein.

Over time, batteries are subject to wear, physical damage, charge material degradation and other factors affecting battery health. Unfortunately, conventional approaches to battery health suffer from the shortcoming that they merely rely on monitoring a charge or discharge voltage/current to assess battery condition. Such approaches cannot easily identify previous battery misuse or present malfunctions because the measurement of proper function relies only on normal electrical flow and a threshold deviation from an established range. In other words, measurement of only charge/discharge current can appear as normal wear and degradation of charge material, rather than early warning of an unhealthy battery.

Accordingly, configurations herein substantially overcome the shortcomings of conventional battery health monitoring by providing a vibrational or mechanical sensing on the battery exterior, and capturing vibrational signals from the battery during charging or discharging. The vibrational signals are captured and compared to preexisting signals indicative of normal and abnormal battery health. Vibrational signals from an unhealthy battery may be matched to vibrational signals of other batteries exhibiting a compromised state for diagnosing a battery or cell under test as healthy or unhealthy.

In further detail, a method of determining battery health includes applying a voltage across a pair of terminals of a battery under observation, and receiving an evaluation signal indicative of a vibration of the battery. Based on a comparison of the evaluation signal to a predetermined set of signals indicative of battery health, the method determines, based on the evaluation signal, a state of health of the battery.

### BRIEF DESCRIPTION OF THE DRAWINGS

The foregoing and other objects, features and advantages of the invention will be apparent from the following description of particular embodiments of the invention, as illustrated in the accompanying drawings in which like reference characters refer to the same parts throughout the different views. The drawings are not necessarily to scale, emphasis instead being placed upon illustrating the principles of the invention.

FIG. 1 is a schematic diagram of a battery environment suitable for use with configurations herein;

FIG. 2 is a diagram of a use case scenario in the environment of FIG. 1;

FIGS. 3A-3B shows conversion from raw time series data to frequency domain waveforms for comparison;

FIGS. 4A-4B show a smoothing function of raw data from a plurality of sensors on a battery under test;

FIG. 5 shows a frequency domain test signal of a progression to overcharge voltage in the environment of FIGS. 1 and 2;

FIGS. 6A-6D show signal processing of evaluation signals from batteries under test for overcharged battery cells; and

FIGS. 7A-7D show signal processing of evaluation signals from batteries under test for previously over-discharged battery cells.

### DETAILED DESCRIPTION

Traditionally, voltage, current, and other conventional electrical characteristics measured from battery terminals are monitored to evaluate battery performance. However, relying solely on these signals may not provide sufficient early warning due to the rapid onset of thermal runaway in LIBs. Additionally, electrical signals drawn from battery storage capacity can fail to distinguish damaged batteries more prone to sudden failure. In contrast, configurations herein demonstrate a use of vibrational characteristics to monitor the health of LIBs.

Battery profiles of various battery states were gathered from vibration signals generated spontaneously by LIBs were collected using sensors placed on the surface of LIB cells during normal charging/discharging cycles, as well as during artificially induced overcharging and overdischarging states. Raw time series signals were first transformed into the frequency domain, using the fast Fourier transform (FFT), and preprocessed with Gaussian smoothing to reduce noise. Advanced data processing techniques, including cosine similarity, singular value decomposition (SVD), principal component analysis (PCA), and t-distributed stochastic neighbor embedding (t-SNE), were employed for data classification to identify battery deviations from a normal health condition.

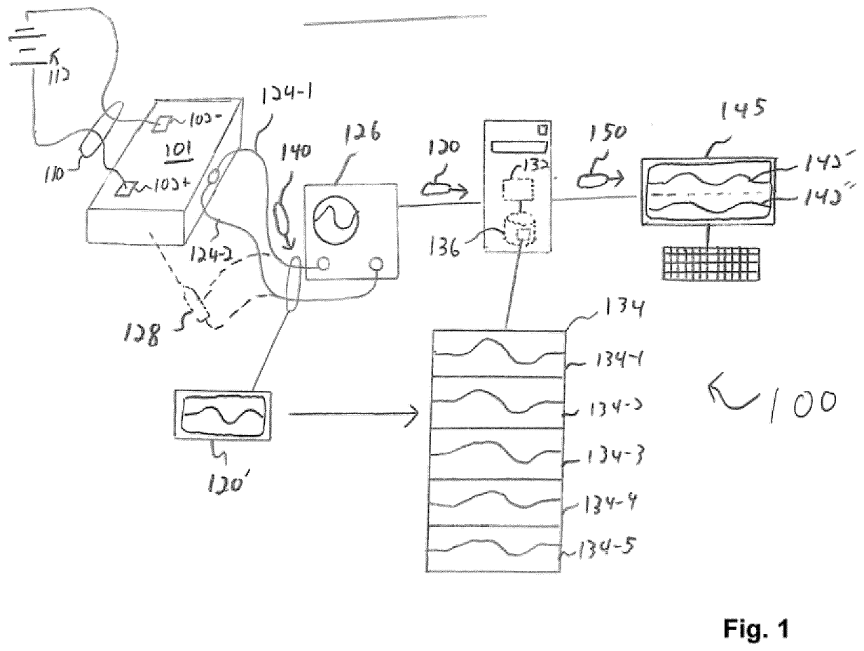

FIG. 1 is a schematic diagram of a battery environment suitable for use with configurations herein. Batteries rely on electrochemical reactions of a charge material in the battery. The chemical makeup of this charge material defines the so-called battery chemistry. In LIBs, this includes metal salts of lithium and other metals such as nickel, manganese, cobalt, aluminum, iron, and other metal salts that form ions of various charge states. Electrons defining the charge state flow from a cathode terminal of the battery to an anode terminal via a load during battery discharge. Charging reverses the process from a grid source to replenish the battery. Complex chemistry that enables LIBs high performance, combined with various operating environments and occasional abusive use scenarios, such as overcharging and overdischarging, can lead to material failure and thermal runaway. Thermal runaway occurs when heat generated by the battery exceeds the cooling capacity of its environment, leading to rapid temperature rises and potential fire.

The electrochemical reactions within the battery cause detectable vibrations on the outer surface of the cell containment, and vary based on the health of the battery. Changes in battery condition often manifest as coupled alterations in electrical, thermal, and mechanical properties. The mechanical properties of a battery are influenced by electrical and thermal processes and can indicate the battery's electrical and thermal status. LIBs produce vibration signals during charging and discharging even without external excitations, allowing for passive health condition monitoring.

Referring to FIG. 1, in a battery monitoring environment 100, a method of determining battery health, includes applying a voltage 110 across a pair of terminals 102+, 102− (102 generally) of a battery 101 under observation. A charge source 112 for charging or an electrical load for discharging may be employed to stimulate the electrochemical reactions inside the battery or cell (a typical “battery” has a pair of terminals 102 internally connected to one or more cells inside the battery containment). An evaluation signal 120 emanates from a sensor 122 adhered to the exterior of the battery 101 or cells therein. A signal processing server 126 or similar computing device receives the evaluation signal 120 indicative of a vibration of the battery 101. A comparator application 132 determines, based on the evaluation signal, a state of health of the battery 101 and renders an indication 150 based on a waveform 140′ of a vibration designated by the evaluation signal 120 and a waveform 140″ of a previous waveform matching the evaluation signal 120.

In operation, the approach connects the charge source 112 or electrical load to the pair of power terminals 102 on the battery 101, and connects sensory leads 124-1 . . . 124-2 (124 generally) to a pair of terminals on the piezoelectric sensor 122 or accelerometer on a side of the battery. It should be noted that the pair of terminals on the piezoelectric sensor 122 element is different than the pair of power terminals 102 for providing for noninterfering monitoring of battery function by not degrading the power or charge current. An alternative configuration provides for an evaluation signal 120 based on a laser 128 or other sensory medium directed towards an exterior of the battery cell 101.

The sensor 122 may be a piezoelectric accelerometer, a specific type of sensor that uses the piezoelectric effect to measure acceleration. It converts mechanical stress (force) from vibration or shock into an electrical charge using materials such as quartz or ceramic, making it ideal for dynamic measurements.

An oscilloscope or signal processor 126 receives a raw electrical signal 140 from the sensor leads 124, and generates a waveform defining the evaluation signal 120. Previous waveforms 134 in a memory 136 on the server are invoked for comparison with the evaluation signal 120. The previous waveforms 134 are a set of waveforms or signals 120′ generated from previous known battery classification states. Any suitable model or storage medium may be employed for gathering the known previous waveforms, however the disclosed approach employs a mathematical analysis of the waveform, as discussed further below. In an example configuration, the previous waveforms 134 depict a classification of normal 134-1, currently overcharged 134-2, currently over discharged 134-3, previously overcharged 134-4 and previously over discharged 134-5. The comparator application 132 compares the evaluation signal 120 to the set of signals 134, and classifies the state of health based on the comparison. This may be represented visually as a rendering device 145 renders a waveform 142′ appearing more similar to one 142″ of the set of signals 134 indicative of battery health.

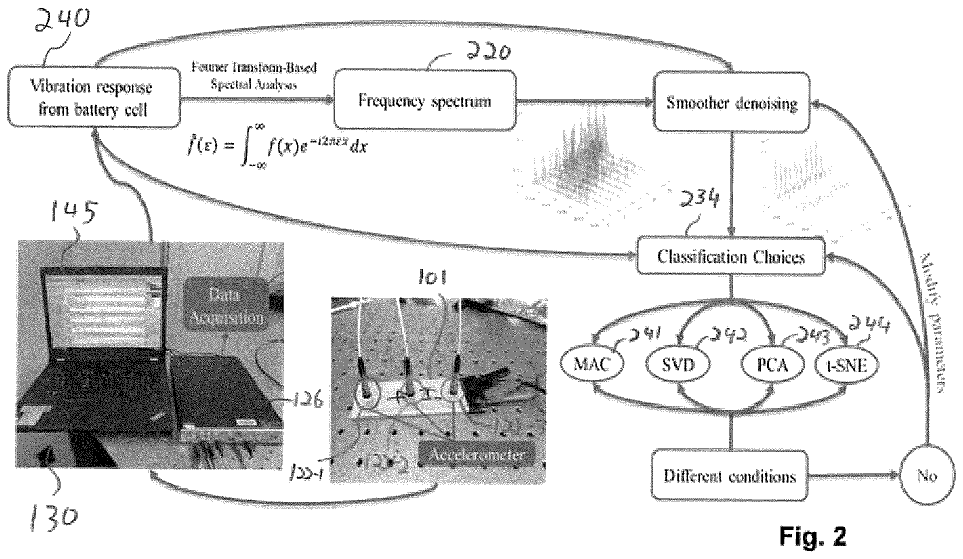

FIG. 2 is a diagram of a use case scenario in the environment of FIG. 1. In configurations disclosed herein, vibration signals were collected using acceleration sensors placed on the surface of the battery 101 or battery cells without external vibration excitation, avoiding interference with the battery's electrical or thermal operation. Vibration signals were recorded from multiple Li-ion pouch rechargeable cells during normal charging and discharging cycles, as well as during artificially induced overcharging and overdischarging states, within the frequency range of 1-23 kHz. The data was first preprocessed using FFT and Gaussian smoothing and further processed with advanced feature extraction and classification techniques, including cosine similarity, singular value decomposition (SVD), principal component analysis (PCA), and t-distributed stochastic neighbor embedding (t-SNE). The findings demonstrate that the vibration spectrum of LIBs exhibited distinctive signatures, corresponding to different LIB states, enabling effective differentiation between healthy and unhealthy batteries.

Referring to FIGS. 1 and 2, the data gathering methodology involved attaching a signal processor 126 including an analog/digital converter to the piezoelectric element 122-1 . . . 122-3 (122 generally), and receiving the evaluation signal 120 from an output of the analog/digital converter. Raw time-series data were first transferred into the frequency domain by a Fourier Transform-based algorithm. The frequency-domain information was then processed to reduce noise. The cleansed data was further classified using various analyses to determine if different LIB states resulted in different vibration signatures.

In the use case of FIG. 2, three sensors 122-1 . . . 122-3 (122 generally) were placed along the length of the battery cell 101, from the tail to the head (where the battery terminals are located). An additional sensor was placed on an optical table to collect environmental background noise. The experiments were subject to environmental noise, such as vibrations from air conditioners, passing trucks, and other acoustic noise induced by devices nearby. The optical table helped attenuate high-frequency noise, reducing the influence from ground excitation, while the data acquisition devices are well isolated such that the electromagnetic interference is minimized. The sensor 122 on the optical table collected environmental noise as a baseline.

The raw vibration response 240 becomes transformed to the frequency spectrum 220 for analysis. Following smoothing, classification selections 234 are made using one of cosine similarity (MAC) 241, singular value decomposition (SVD) 242, principal component analysis (PCA) 243, and t-distributed stochastic neighbor embedding (t-SNE) 244.

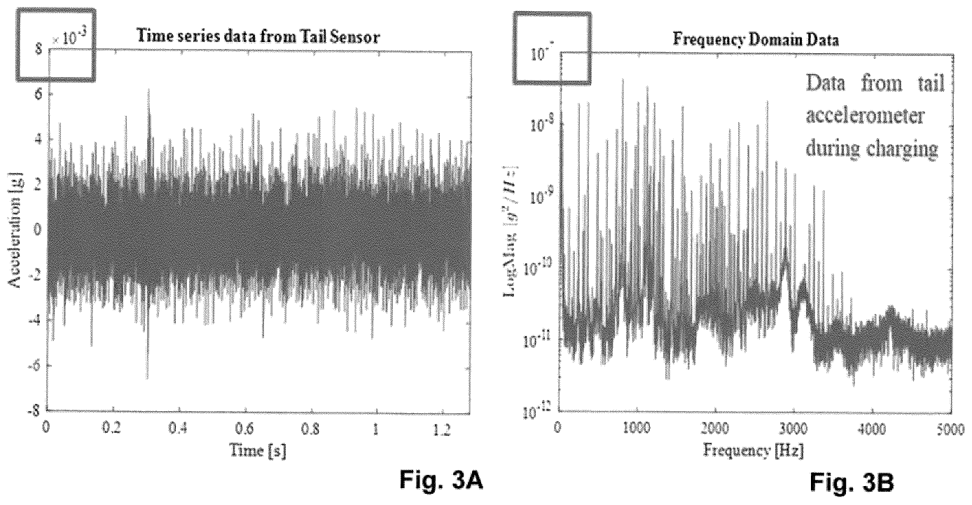

FIGS. 3A-3B shows conversion from raw time series data to frequency domain waveforms for comparison. Referring to FIGS. 1-3B, an energy level of the raw gathered electrical signals 140 is rather low. FIG. 3A shows the time series, and FIG. 3B depicts the frequency domain representation from the sensor located at the tail of Li-ion battery 101 during charging. As shown in FIG. 3A, the amplitude fluctuates roughly in between ±2×10⁻³ g, while in the frequency domain, 3B shows that the amplitude of the power spectrum is approximately on the order of 10⁻¹⁰ g²/Hz.

The setup includes adhering the piezoelectric element sensor 122 to the exterior of the battery cell 101, and passively sensing an electrical signal from the piezoelectric element resulting from vibratory oscillations of the battery. In the case of multiple sensors 122, signals may be averaged or combined, or individual readings used in parallel. The signal processor 126 receives the electrical signal 140 from the piezoelectric sensor 122, passes the electrical signal 140 through the A/D converter, and performs further preprocessing, such as smoothing to remove noise, and converts the electrical signal 140 into the evaluation signal 120. This converts the raw electrical signal 140 into a frequency domain to generate the evaluation signal 120.

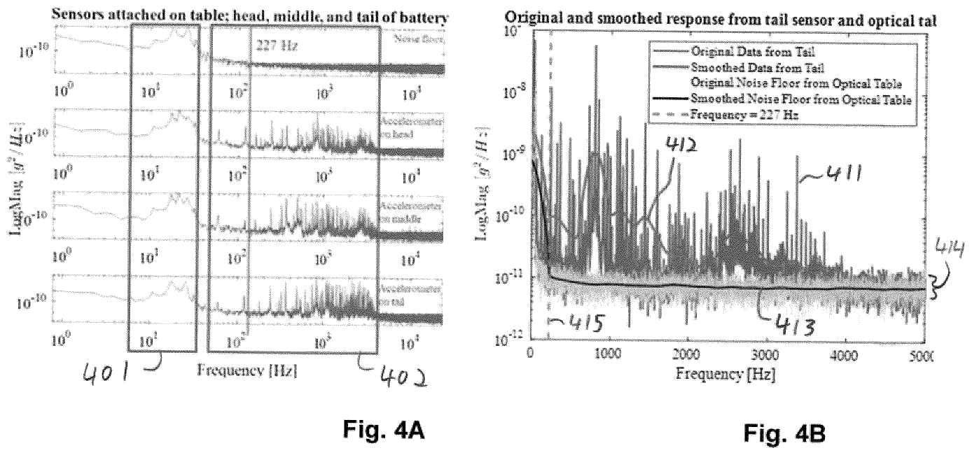

FIGS. 4A-4B show a smoothing function of raw data from a plurality of sensors on a battery under test. Referring to FIGS. 1-4B, following the setup from FIG. 2, 3 sensors attach to the tail, middle, and head of the battery 101, and a further sensor takes a control measurement of background noise on the optical table upon which the battery 101 resides. As the data is collected from 4 sensors, FIG. 4A illustrates the typical power spectrum of each of the four sensors 122. Ch1 is the sensor on the optical table. Sensors for Ch2, Ch3, and Ch4 are attached to the battery from the tail to the head, with the head being the side of the battery terminals, as shown in FIG. 2. Significant differences between the data collected on the optical table and the data collected on the LIB cell were observed. It is notable that in the low-frequency range, spectra of all three accelerometers attached to the battery exhibited the same shape as the spectrum of the noise floor, as shown in the left-side box of FIG. 4A.

Data preprocessing is employed on the raw electrical signal 140 to eliminate noise and improve data classification performance. Gaussian smoothing is a widely used method in data processing to reduce noise and enhance data quality. In the disclosed approach, Gaussian smoothing was employed to effectively remove high-frequency noise and reveal underlying patterns in the data. FIG. 4B compares the unprocessed data 411 with the preprocessed data after Gaussian smoothing 412. Smoothing effectively removed undesirable noise and revealed a clear trend in the power spectrum. The preprocessed data were then further analyzed using multiple classification techniques. In addition, FIG. 4B also shows the raw and smoothed noise floor 414 and a black solid line 413, respectively, from the accelerometer attached to the optical table. Comparing the signal from the battery 412 and the background noise 413, it is clear that the peaks in the higher frequency range only existed in data collected from the battery cell 101. It is noticeable that the noise floor 413 is essentially flat in a frequency range higher than 227 Hz (separated by the vertical dashed line 415). As a result, in the frequency region higher than 227 Hz, signals from the battery exhibited significant features, as shown in the right-side box 402.

It may be noted that the data collected on the cell 412 exhibited the same shape as that of the noise floor 413 in the frequency range lower than 227 Hz, as well as a very different trend in the frequency range higher than 227 Hz. FIG. 4B also includes the outcome performed by the Gaussian smoother, where:

$$y ( i ) = \frac{{\sum }_{j = - k}^{k} x [ i - j ] \cdot w [ j ]}{{\sum }_{j = - k}^{k} w [ j ]}$$

denotes the smoothed value at the index i, x(i−j) is the original data at the index

$$i - j , w ( j ) = {e}^{- \frac{{j}^{2}}{2 {σ}^{2}}}$$

is the Gaussian kernel weight at the position j, k is the window size parameter, and σ is the standard deviation of the Gaussian kernel.

The discussion above designates the signal or waveform generated from battery 101 vibration depicts deterministic responses indicative of battery health. Configurations herein receive the raw piezoelectric signal 140 at the signal processor 126 for analysis according to several classifications. The evaluation signal 120 may be compared to the set of signals 134 using at least one of a cosine similarity, singular value decomposition (SVD), principal component analysis (PCA), and t-distributed stochastic neighbor embedding (t-SNE) computation.

Cosine similarity is a statistical indicator of differences between vectors. It is a least-squares-based linear regression analysis that is more sensitive to large differences rather than smaller values. It provides a measure of consistency between two vectors via the cosine value of the relative angle in between. The formula for cosine similarity score (ϑ) is:

$$ϑ ( {φ}_{r} , {φ}_{q} ) = \frac{{φ}_{r} \cdot {φ}_{q}}{‖ {φ}_{r} ‖ ‖ {φ}_{q} ‖} \qquad Equation 1$$

where φᵣ is the r-th test power spectrum, and φ_{q} is the q-th test power spectrum.

Equation 1 calculates the correlation between these vectors and returns a value between 0 to 1, with the value close to 1 representing a strong correlation (parallel), and a value close to 0 indicating a weak correlation (perpendicular). For configurations herein, this approach was employed to compare if these test vectors are similar within certain health groups.

SVD is widely used in digital image processing, due to its high performance in dimensionality reduction, data compression, and denoising. Among all the variations of the SVD algorithm, Full SVD was chosen for this study due to its straightforward mathematics and clear interpretability. Each data set in this study is 2×n dimensions. Thus, several data sets can be combined into an m×n dimensions data set and considered as a high-dimensional image suitable for SVD processing. Considering the data as a m×n matrix A, the SVD can be represented as A=USV^{T}, where U and V are orthogonal matrices, and S is a diagonal matrix with singular values to A. In configurations herein, matrix V was used to obtain reduced dimension data facilitating the classification of different batteries conditions.

PCA is a specific case of SVD that computes the dominant vectors in the data set. It essentially performs SVD on the covariance matrix of the data set, focusing on maximizing the variance. PCA follows five main steps. The first step is the standardization of the data in Equation 2:

$${z}_{i j} = \frac{{x}_{i j} - {μ}_{j}}{{σ}_{j}} \qquad Equation 2$$

where xᵢⱼ is the i-th observation of the j-th variable, μⱼ is the mean of the j-th variable, σⱼ is the standard deviation of j-th variable, and zᵢⱼ is the standardized data. The second step is to calculate the covariance matrix, as described in Equation 3:

$$C = \frac{1}{n - 1} {Z}^{T} Z \qquad Equation 3$$

where Z is the standardized data matrix, and n is the number of observations. The third step calculates the eigenvalues and eigenvectors of the covariance matrix C. The eigenvalue can be calculated by Cv=λv, where v is an eigenvector, and λ is the corresponding eigenvalue. Then the eigenvectors v₁, v₂, . . . , vₖ form the principal components of matrix V of the data, and each eigenvalue λ₁, λ₂, . . . , λₖ form the amount of variance explained by the corresponding component. In the fifth step, the new data set is formed, based on eigenvectors matrix, as Z_{new}=ZV.

Due to its ease of optimization and high performance, t-SNE is widely used in high-dimensional data visualization. Despite being a resource-intensive algorithm, in this study, t-SNE was found to be more effective than SVD, PCA, or cosine similarity in revealing the differences among multiple LIB states. There are three principal steps in t-SNE. The first step converts high-dimensional distances into probabilities that are proportional to the similarity of objects xᵢ and xⱼ, as shown in Equation 4:

$${p}_{j \vert i} = \frac{exp ( - \frac{{‖ {x}_{i} - {x}_{j} ‖}^{2}}{2 {σ}_{i}^{2}} )}{{\sum }_{k \neq i} exp ( - \frac{{‖ {x}_{i} - {x}_{k} ‖}^{2}}{2 {σ}_{i}^{2}} )} \qquad Equation 4$$

where ∥xᵢ−xⱼ∥ is the Euclidean distance between two points i and j, σᵢ is the variance of the Gaussian kernel. Then, the probability is proportional to the similarity of low-dimensional points yᵢ and yⱼ is calculated by Equation 5 below:

$${q}_{j \vert i} = \frac{exp ( - {‖ {y}_{i} - {y}_{j} ‖}^{2} )}{{\sum }_{k \neq i} exp ( {‖ {y}_{i} - {y}_{j} ‖}^{2} )} \qquad Equation 5$$

Thirdly, SNE minimizes the sum of Kullback-Leibler divergence (KL divergence) over all datapoints using a gradient descent method, the locations of the points yᵢ are determined by minimizing the KL divergence of the distribution P from the distribution Q, the cost function C is shown as Equation 6.

$$C = {\sum }_{i} K L ( {P}_{i} ‖ {Q}_{i} ) = {\sum }_{i} {\sum }_{j} {p}_{j \vert i} log \frac{{p}_{j \vert i}}{{q}_{j \vert i}} \qquad Equation 6$$

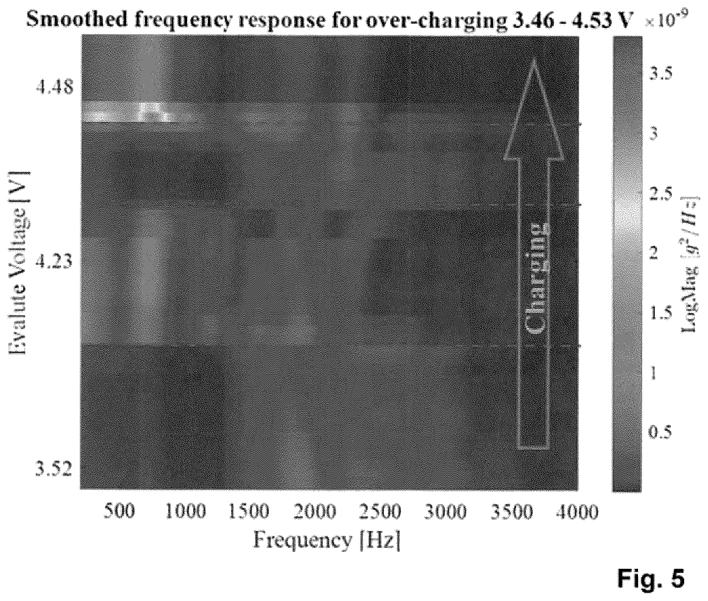

FIG. 5 shows a frequency domain test signal of a progression to overcharge voltage in the environment of FIGS. 1 and 2. In general, comparison of the evaluation signal is based on a power spectrum density and alignment with one of the know battery states: normal, currently overcharged, currently over discharged, previously overcharged, previously over discharged.

In the case of an overcharged state, referring to FIG. 5, changes in the power spectrum at a few key voltages were observed. The normal operating voltage range of the tested batteries was 3.2-4.2 V. When a battery was charged to a voltage exceeding 4.2 V, it was considered overcharged. FIG. 5 shows the spectrogram of a battery charged from 3.46 V to an overcharged state of 4.53 V at a constant current of 0.5 C. Four distinctive stages can be distinguished: V<4.0 V, 4.0-4.3 V, 4.3-4.42 V, and 4.42-4.53 V, as shown in FIG. 5. These four stages exhibited notable trends: When V<4.0 V, i.e., normal voltage range, a significant response was observed in 2000-3000 Hz; when the voltage was raised to 4.0-4.3 V, the noticeable response moved to a lower frequency range. Raising the voltage further to 4.3-4.42 V, the noticeable response moved to a higher frequency range. Finally, raising the voltage to 4.42-4.53 V resulted in significant response in a lower frequency range. However, the responses observed in the first and third stages are relatively similar and require further signal analysis.

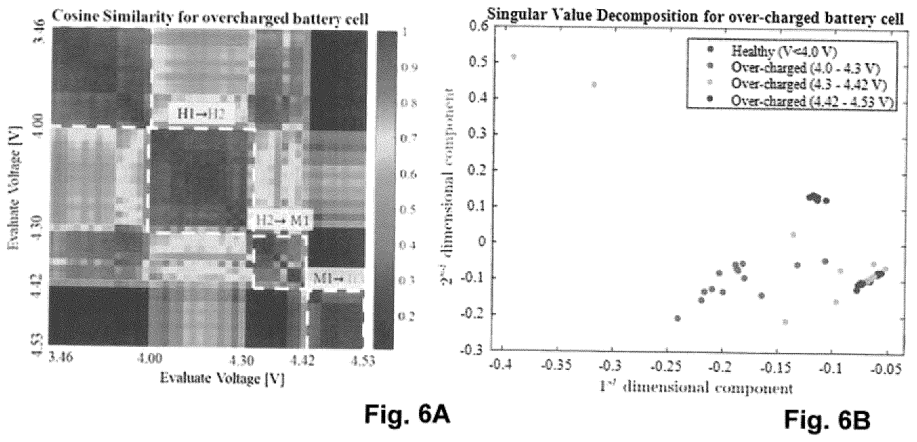

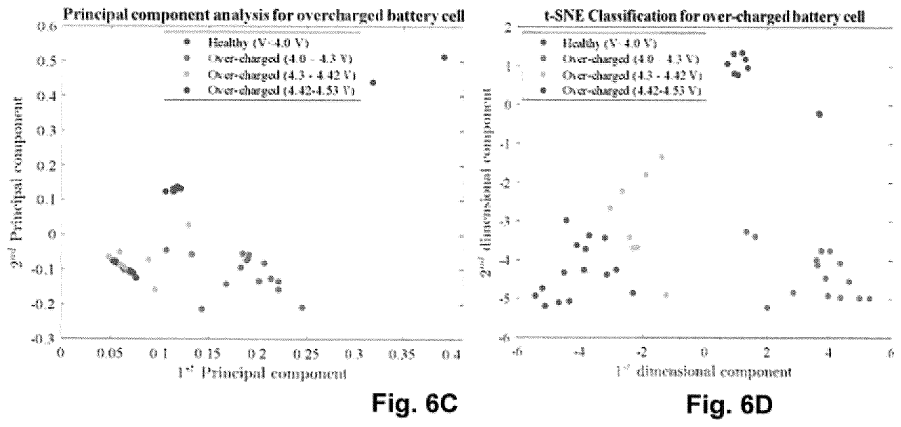

FIGS. 6A-6D show signal processing of evaluation signals from batteries under test for overcharged battery cells. Referring to FIGS. 6A-6D, FIG. 6A shows classification results for LIB overcharging (3.46-4.53 V) from cosine similarity; FIG. 6B shows classification results for LIB overcharging (3.46-4.53 V) from SVD; FIG. 6C shows classification results for LIB overcharging (3.46-4.53 V) from PCA; and FIG. 6D shows classification results for LIB overcharging (3.46-4.53 V) from t-SNE.

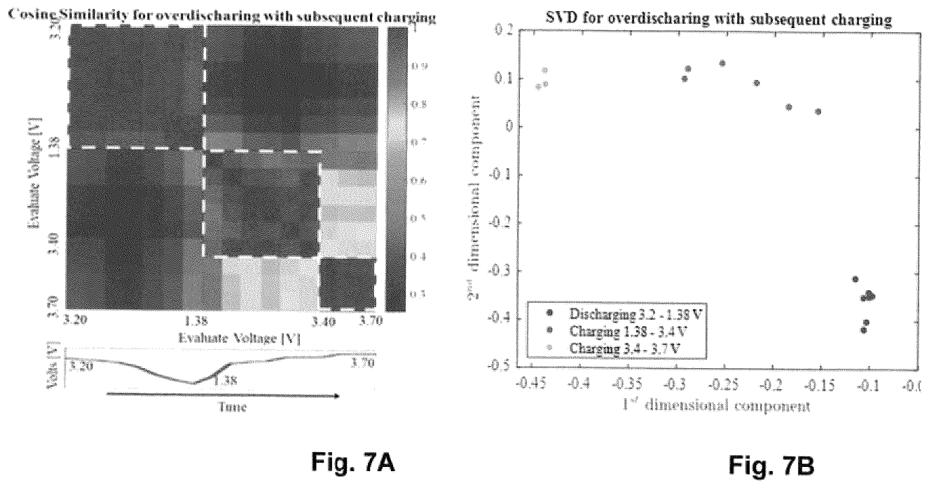

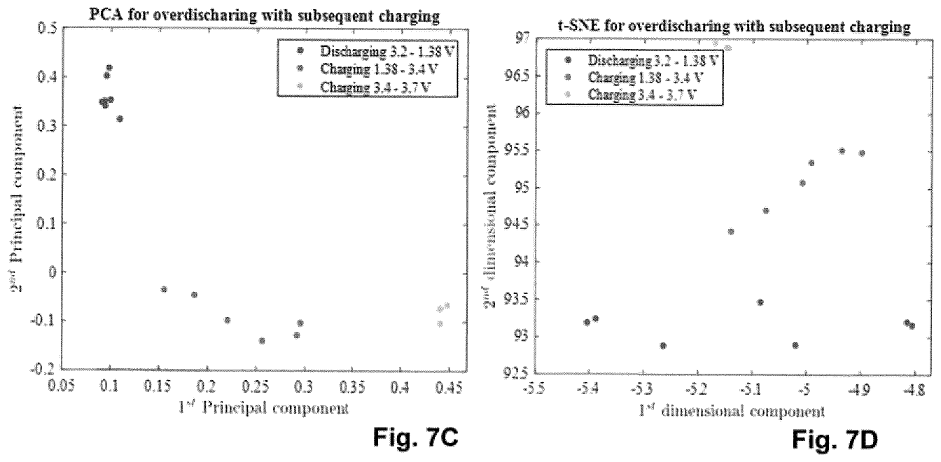

FIGS. 7A-7D show similar signal processing of evaluation signals from batteries under test, but for previously over-discharged battery cells. FIG. 7A shows classification results of data from over-discharging from 3.2 to 1.38 V and subsequent charging from 1.38 to 3.7 V: for FIG. 7A: Cosine similarity with evaluate voltage curve; FIG. 7B: SVD; FIG. 7C: PCA; and for FIG. 7D: t-SNE.

While the system and methods defined herein have been particularly shown and described with references to embodiments thereof, it will be understood by those skilled in the art that various changes in form and details may be made therein without departing from the scope of the invention encompassed by the appended claims.

What is claimed is:

1. A method of determining battery health, comprising:
applying a voltage across a pair of terminals of a battery under observation;
receiving an evaluation signal indicative of a vibration of the battery; and
determining, based on the evaluation signal, a state of health of the battery.

2. The method of claim 1, wherein determining the state of health results in a classification of normal, currently overcharged, currently over discharged, previously overcharged, previously over discharged.

3. The method of claim 1 wherein the evaluation signal is based on a sensor adhered to an exterior of the battery cell.

4. The method of claim 1 wherein the evaluation signal is based on a laser directed towards an exterior of the battery cell.

5. The method of claim 1 further comprising:
adhering a piezoelectric element to the exterior of the battery cell and
passively sensing an electrical signal from the piezoelectric element resulting from vibratory oscillations of the battery; and
converting the electrical signal into the evaluation signal.

6. The method of claim 5 further comprising:
attaching an analog/digital converter to the piezoelectric element; and
receiving the evaluation signal from an output of the analog/digital converter.

7. The method of claim 2 further comprising:
generating a set of signals from known battery classification states;
comparing the evaluation signal to the set of signals; and
classifying the state of health based on the comparison.

8. The method of claim 1 further comprising:
receiving an electrical signal from a piezoelectric element attached to an exterior or the battery;
converting the electrical signal into a frequency domain for generate the evaluation signal.

9. The method of claim 7 further comprising;
comparing the evaluation signal to the set of signals using at least one of a cosine similarity, singular value decomposition (SVD), principal component analysis (PCA), and t-distributed stochastic neighbor embedding (t-SNE) computation.

10. The method of claim 5 further comprising:
connecting a charge source or electrical load to a pair of power terminals on the battery; and
connecting sensory leads for sensing the electrical signal to a pair of terminals on the piezoelectric element, the pair of terminals on the piezoelectric element different than the pair of power terminals.

11. A battery analyzer device, comprising:
a vibration sensor affixed to an external surface of a battery;
a signal processing server connected to the vibration sensor and configured for receiving an evaluation signal indicative of a vibration of the battery; and
a comparator application configured to determine, based on the evaluation signal, a state of health of the battery.

12. The device of claim 11, further comprising:
a memory having a set of signals from known battery classification states, the signal processing server configured to compare the evaluation signal to the set of signals, and render a classification of the state of health based on the comparison.

13. A computer program embodying program code on a non-transitory computer readable storage medium that, when executed by a processor, performs steps for implementing a method of determining battery health, the method comprising:
applying a voltage across a pair of terminals of a battery under observation;
receiving an evaluation signal indicative of a vibration of the battery; and
determining, based on the evaluation signal, a state of health of the battery.
